(19) United States
(12) Patent Application Publication
(10) Pub. No.: US 2017/0372870 A1
(43) Pub. Date: Dec. 28, 2017

(54) Inductive Plasma Source

(71) Applicant: Mattson Technology, Inc., Fremont, CA (US)

(72) Inventors: Valery A. Godyak, Brookline, MA (US); Charles Crapuchettes, Santa Clara, CA (US); Vladimir Nagorny, Tracy, CA (US)

(21) Appl. No.: 15/650,164

(22) Filed: Jul. 14, 2017

Related U.S. Application Data
(63) Continuation of application No. 13/388,309, filed on Feb. 1, 2012, now abandoned.
(60) Provisional application No. 61/236,081, filed on Aug. 21, 2009.

(51) Int. Cl. H01J 37/32; H05H 1/46

(52) U.S. Cl. CPC H01J 37/3211; H01J 37/32119; H01J 37/321; H05H 1/46; H01J 37/32174; H01J 37/32137; H01J 37/32449; H01J 37/32651; H05H 2001/4652; H01J 37/32183

(57) ABSTRACT

Methods and apparatus to provide efficient and scalable RF inductive plasma processing are disclosed. In some aspects, the coupling between an inductive RF energy applicator and plasma and/or the spatial definition of power transfer from the applicator are greatly enhanced. The disclosed methods and apparatus thereby achieve high electrical efficiency, reduce parasitic capacitive coupling, and/or enhance processing uniformity. Various embodiments comprise a plasma processing apparatus having a processing chamber bounded by walls, a substrate holder disposed in the processing chamber, and an inductive RF energy applicator external to a wall of the chamber. The inductive RF energy applicator comprises one or more radiofrequency inductive coupling elements (ICEs). Each inductive coupling element has a magnetic concentrator in close proximity to a thin dielectric window on the applicator wall.

### PRIORITY CLAIM

This application claims the benefit of priority of U.S. Provisional Patent Application No. 61/236,081, filed Aug. 21, 2009, which is incorporated herein by reference for all purposes.

### FIELD

The present disclosure relates generally to plasma generation and, more particularly to an apparatus and method for processing in a plasma source having high coupling efficiency.

### BACKGROUND

Low pressure inductively coupled plasmas (ICPs) are used in the manufacture of devices such as integrated circuits, micromechanical devices, flat panel displays, and other devices. Inductive coupling is often preferred over capacitive coupling for these applications because the current flow in an ICP is driven by an electromotive force having no associated scalar voltage differences. Capacitive coupling, on the other hand, tends to increase the plasma potential relative to various surfaces, causing parasitic currents, discharges, arcing and/or other unwanted currents between the plasma and various surfaces in a processing chamber. Capacitive coupling can also produce large voltages (e.g. increase in plasma potential), accelerating ions onto surfaces at high energy. In this regard, capacitive coupling can sputter surface material, release contamination into the process chamber, and/or damage devices on a substrate. Additionally, capacitively coupled plasma (CCP) reactors are limited in the density of the plasma that can be produced, since capacitive coupling by stochastic heating is rapidly reduced as the plasma density increases and the sheath gets thinner.

Generally, ICPs for processing are maintained within a plasma processing apparatus using an applicator (often referred to as an antenna) to couple high frequency electromagnetic energy through a large dielectric window of a processing chamber. In some apparatus the applicator is a single coil. Other ICP processing equipment includes multiple coils. The dielectric window is generally made of a relatively low loss material such as quartz, alumina, or another ceramic.

Plasma processing is often performed at relatively low pressure. For example, a preselected operating pressure for plasma etching and/or plasma assisted chemical vapor deposition can be in the range of 0.1 milliTorr to 100 Torr, depending on the application. However pressures outside of this range are also operable in some applications.

The large dielectric window in conventional ICP processing apparatus commonly spans an upper surface of a processing chamber. Electromagnetic flux coupled through this dielectric window can power an ICP in chamber gas below the window. A workpiece or substrate being processed is commonly supported below the dielectric window on a horizontal substrate holder or chuck in the chamber. The dielectric window can be flat, although dome shaped windows have been used in some ICP processing apparatus.

Electromagnetic theory teaches that inductively coupled plasma current is energized by the electromotive force (EMF) arising from the periodic change in high frequency magnetic flux surrounding the current-carrying plasma volume. Nevertheless, conventional processing equipment has often been designed to provide an intense magnetic field, rather than to optimize the amount of flux surrounding a current-carrying region of plasma. Since the electromotive force is proportional to the integral amount of flux encircling a current-carrying region of plasma, merely having strong magnetic field lines does not ensure efficient coupling.

In many applications, such as plasma etching or plasma assisted chemical vapor deposition for the fabrication of devices, it is imperative to have a relatively uniform plasma over the various areas of a substrate being processed. With regard to uniformity, a flat dielectric window is often preferred to a dome shaped window, because a flat window provides a relatively uniform distance between the various positions where a plasma receives power and a workpiece on a substrate holder. However it has been difficult to scale RF energy applicators above flat windows and/or to obtain efficient coupling and a uniform plasma density over relatively large substrate areas.

Various problems can arise where power is coupled through a thick window covering a wide area. A flat dielectric window covering the top of a vacuum processing chamber must be sufficiently thick to withstand mechanical forces arising from the difference between external atmospheric pressure and a vacuum in the chamber. A quartz window covering a chamber that is large enough to process a flat 300 mm diameter semiconductor wafer (typically such a window is about 0.5 m diameter) must be at least a few centimeters thick to withstand this pressure and provide an acceptable margin of safety. In practice, thicknesses of about 2 to 5 cm have generally been used. Moreover, as a chamber is scaled to process still larger substrate sizes, the dielectric window thickness requirement increases in proportion to the chamber diameter.

Coupling to a plasma through thick windows has been inefficient. Applicator coils adjacent a thick dielectric window (e.g. 1 cm or more) over a chamber space commonly produce an appreciable proportion of magnetic flux lines that loop within the window and do not reach, and/or barely reach the interior chamber space comprising plasma. Where the magnetic flux does not encircle a localized plasma current, power coupling is often weak and inefficient.

To mitigate weak coupling, an applicator must be powered by relatively high RF voltages to couple a predetermined amount of power into a plasma. Such high RF voltage is problematic because it can provoke harmful arcing and/or sparking, and because the amount of power lost in matching and power coupling systems generally goes up as the square of applied voltage. Furthermore, high voltage can make it difficult or unfeasible to operate in a purely inductive mode and to avoid substantial capacitive coupling. This is particularly problematic where a process requires a relatively low density inductively coupled plasma. Relatively high power losses in the applicator and/or matching network can also cause plasma instabilities.

It is difficult to scale up an inductive RF energy applicator having a single coil element. One difficulty arises from the laws of physics which dictate that the inductance of a coil turn increases in proportion to its radius. Since the RF voltage required to excite a predetermined current in an applicator coil is proportional to its inductance, it is apparent that disproportionately higher RF voltages are necessary to power large coils, particular where there are uniformly spaced turns. This problem can be mitigated in part by using an applicator having a plurality of smaller inductive coupling coil elements distributed over a window, wherein each coil has a relatively less inductance.

To increase relative amount of magnetic flux reaching into the chamber and improve coupling, conventional ICP applicator coils have been positioned close to the plasma. For example, U.S. Pat. No. 6,259,309 to Bhardwaj et al. situates conventional planar annual coils immediately above a narrow thin dielectric window ring on the top wall of a chamber. The narrow dielectric ring was supported with a separate structure having sufficient strength to hold off atmospheric pressure.

Although this conventional configuration allows greater amounts of magnetic flux to reach through the window, the resultant flux lines extend generally parallel to the window and within a thin layer immediately adjacent to the window.

It has been suggested that spatial uniformity in a plasma processing chamber might be improved by directing selected amounts of current into different applicator coils situated at various positions adjacent to a dielectric window. However, measurements have shown there is relatively poor spatial correlation between the individual coil currents and the plasma density adjacent each coil.

In addition, directing selected amounts of power to different coils is typically performed in existing applicators based on power measurements performed at the match network for the coils and not based on real power delivered to plasma. These power measurements can be very sensitive to changes in current applied to the coils. Moreover coil losses, antenna cage losses, interference from adjacent coils, and losses inside the chamber must be taken into account. Parameters are different for every coil and applicator, requiring process parameters to be tweaked for every coil and for every applicator. Consequently, this approach has been problematic.

Plasma non-uniformities can also arise from non-uniform feed gas introduction. In some capacitive plasma processing apparatus, an applicator electrode above a workpiece support has “showerhead” gas distribution holes that can be used to selectively introduce feed gas into the processing chamber in a uniform manner. However, in ICP processing apparatus having a relatively thick flat or dome shaped dielectric window, it has been impractical to provide feed gas holes in such windows owing to structural/mechanical limitations and/or cost. In addition, locating feed gas injection holes proximate applicator coils can result in electromagnetic energy interacting with the feed gas prior to the feed gas entering the process chamber. Hence feed gas has generally been introduced plasma processing equipment in other ways.

For example, there is ICP processing apparatus where feed gas is introduced into the processing chamber through a plurality of feed injectors at various positions around the periphery of the substrate and/or below the substrate holder. It has been relatively difficult to effectuate uniform gas distribution over the substrate using such means. Furthermore, such invasive injectors within a chamber can degrade plasma uniformity.

Further plasma non-uniformities can arise from parasitic capacitive coupling of the coils with the plasma. Electrostatic or Faraday shields between the coils and the ICP can be used to reduce capacitive coupling of the coils with the plasma. However, Faraday shields can significantly reduce inductive coupling and can inflict a significant loss in RF power, resulting in reduced ICP power transfer efficiency for the applicator. One primary reason that such shields decrease coupling efficiency is that interposing the shield between the inductive coupling element and the dielectric window, necessarily increases the separation of the applicator to the chamber interior, unless the shield is extremely thin. U.S. Pat. No. 6,056,848 to Daviet discloses a thin film electrostatic shield that is electromagnetically thin such that inductive power passes through the shield to sustain the plasma while capacitive coupling is substantially attenuated. We have however found that even electromagnetically thick shields that are nevertheless mechanically thin (so as to minimally move the coupling element out from the chamber interior) provide excellent performance. Also, while existing Faraday shields may be effective at eliminating capacitive coupling, sometimes it is desirable only to reduce the capacitive coupling to eliminate sputtering, but to leave some capacitive coupling to create small targeted plasma non-uniformities if desired and to help ignite the plasma.

It can be seen that there has been a long felt need for ICP processing apparatus and methods that provide high coupling and/or can be scaled up to process large substrate sizes. There has also been a need for ICP processing apparatus and methods that provide high power transfer efficiency and a high degree of processing uniformity over large areas. Furthermore, there is a long felt need for scalable ICP processing apparatus and methods that are stable at low power and/or low plasma density. Still further, there is a need for ICP processing apparatus and methods that provide for power control based on real power delivered to the ICP. ICP processing apparatus and methods that can effectuate preselected feed gas distribution over large areas and can effectively manage parasitic capacitive coupling would be particularly useful.

### SUMMARY

Aspects and advantages of the invention will be set forth in part in the following description, or may be obvious from the description, or may be learned through practice of the invention.

One exemplary embodiment of the present disclosure is directed to an apparatus for processing a substrate in a plasma. The apparatus includes a processing chamber having an interior space operable to confine a process gas and a substrate holder in the interior of the processing chamber operable to hold a substrate. The apparatus further includes at least one dielectric window constituting a portion of a wall of the processing chamber. The apparatus further includes an inductive applicator disposed external to the processing chamber. The inductive applicator includes at least one inductive coupling element, and in particular embodiments includes a plurality of inductive coupling elements. The inductive coupling element includes a coil portion and a magnetic flux concentrator of magnetically permeable material. The magnetic flux concentrator has a first pole area and a second pole area. The first pole area and the second pole area generally face the at least one dielectric window. The inductive coupling element further includes a conductive shield disposed at least partially around the magnetic flux concentrator. In particular embodiments, the conductive shield can be comprised of aluminum, copper, silver, or gold.

In accordance with aspects of this particular embodiment, when the inductive coupling element is energized, a radiofrequency magnetic flux emanates from the magnetic flux concentrator directionally into the interior of the processing chamber such that a substantial portion of the magnetic flux emerges from the first pole area through the at least one dielectric window into the interior of the processing chamber and such that a substantial portion of the magnetic flux returns back from the interior of the processing chamber through the at least one dielectric window to the second pole area of the magnetic flux concentrator.

In a variation of this exemplary embodiment, the first pole area and the second pole area of the inductive coupling element can be separated by a gap distance. The first pole area and the second pole area can be located less than about one half, but preferably less than one fourth of the gap distance from the interior of the processing chamber, such as less than about one eighth of the gap distance. For example, in a particular embodiment, the magnetic flux concentrator can be disposed on the at least one dielectric window. The thickness of the dielectric window can be less than about one fourth of the gap distance, such as less than about one eighth of the gap distance.

In another variation of this exemplary embodiment, the apparatus can include a plurality of feed gas conduits configured to deliver process gas into the interior of the process chamber. At least one of the plurality of feed gas conduits can be operable to provide process gas to the interior of the process chamber through a feed hole disposed proximate to the inductive coupling element. The conductive shield of the inductive coupling element can separate the coil portion of the inductive coupling element from at least one the plurality of feed gas conduits. In a particular embodiment, at least one of the plurality of feed gas conduits can be configured to be controlled to admit a preselected flow rate of process gas into the interior of the processing chamber.

In yet another variation of this exemplary embodiment, the inductive coupling element is coupled to an RF energy source through a match circuit and at least one resonant capacitor. The apparatus can include a power measurement device coupled between the match circuit and the resonant capacitor. The apparatus can further include a control loop configured to control RF power provided to the inductive coupling element based at least in part on signals received from the power measurement device.

In still a further variation of this exemplary embodiment, the apparatus can include an electrostatic shield disposed on the at least one dielectric window between the inductive coupling element and the interior of the process chamber. The electrostatic shield can include an array of thin metal strips disposed on the at least one dielectric window. Each of the thin metal strips can be disposed in a direction substantially normal to the coil portion of the inductive coupling element. In a particular embodiment, the array of thin metal strips are coupled by a conductive loop that may or may not be broken. In variations of this particular embodiment, the conductive loop can be grounded, floating, or coupled to a voltage source. In another variation of this exemplary embodiment, the electrostatic shield can include a flat sheet running parallel to the coil portion of the inductive coupling element. The flat sheet can include at least one discontinuity. The size and configuration of the discontinuity can be sufficient to prevent circulating currents.

Another exemplary embodiment of the present disclosure is directed to a method of processing a substrate. The method includes placing a substrate on the substrate holder within the interior of a processing chamber of a processing apparatus; admitting a process gas into the interior of the processing chamber; maintaining a preselected pressure below 100 Torr in the processing chamber; energizing at least one inductive applicator outside of the processing chamber with radiofrequency power to generate a substantially inductive plasma in the interior of the processing chamber; and processing the substrate with the inductive plasma in the processing chamber.

In particular aspects of this exemplary embodiment, the processing chamber includes at least one dielectric window constituting a portion of a wall of the processing chamber. The inductive applicator includes at least one inductive coupling element, such as a plurality of inductive coupling elements. The at least one inductive coupling element includes a coil portion and a magnetic flux concentrator of magnetically permeable material. The magnetic flux concentrator has a first pole area and a second pole area. The first pole area and the second pole area generally face the at least one dielectric window. The inductive coupling element includes a conductive shield disposed at least partially around the magnetic flux concentrator. In particular embodiments, the conductive shield can be comprised of gold, aluminum, copper, or silver.

In further particular aspects of this exemplary embodiment, the inductive coupling element is operable to circulate a radiofrequency magnetic flux from the magnetic flux concentrator directionally into the interior of the processing chamber through the at least one dielectric window such that a substantial portion of the magnetic flux emerges from the first pole area through the at least one dielectric window into the interior of the processing chamber and such that a substantial portion of the magnetic flux returns back from the interior of the processing chamber through the at least one dielectric window to the second pole area of the magnetic flux concentrator.

In a variation of the exemplary embodiment, the first pole area and the second pole area of the inductive coupling element can be separated by a gap distance. The first pole area and the second pole area can be located less than about one fourth of the gap distance from the interior of the processing chamber, such as less than about one eighth of the gap distance. For example, in a particular embodiment, the magnetic flux concentrator can be disposed on the at least one dielectric window. The thickness of the dielectric window can be less than about one fourth of the gap distance, such as less than about one eighth of the gap distance.

In another variation of this exemplary embodiment, the method can further include selectively distributing power between a plurality of inductive coupling elements to obtain a plasma profile. In particular embodiments, selectively distributing power can include providing energy to at least one of the plurality of inductive coupling elements from an RF energy source through a match circuit and at least one resonant capacitor and measuring real power delivered to at least one of the plurality of inductive coupling elements using a power measurement device coupled between the match circuit and the at least one resonant capacitor. The method can further include determining real power delivered to the plasma based at least in part on power measured using the power measurement device and controlling the energy provided to at least one of the plurality of inductive coupling elements from the RF energy source based at least in part on the real power delivered to the plasma.

In a further variation of this exemplary embodiment, admitting a process gas into the interior of the processing chamber can include admitting a process gas through a plurality of feed gas conduits configured to deliver process gas into the interior of the process chamber. At least one of the plurality of feed gas conduits can provide gas to the interior of the process chamber through a feed hole disposed proximate the inductive coupling element. The method can further include controlling the flow rate of process gas in at least one of the feed gas conduits to spatially tune the distribution of charged and neutral species within the plasma.

In still a further variation of this exemplary embodiment, the processing apparatus can include an electrostatic shield disposed between the inductive coupling element and the at least one dielectric window. The electrostatic shield can include an array of thin metal strips disposed on the at least one dielectric window in a direction substantially normal to the coil portion of the inductive coupling element. In a particular embodiment, the array of thin metal strips can be coupled by at least one conductive loop. The method can include adjusting the voltage applied to the at least one conductive loop to tune capacitive coupling to the plasma in the interior of the process chamber. In another variation of this exemplary embodiment, the electrostatic shield can include a flat sheet running parallel to the coil portion of the inductive coupling element. The flat sheet can include at least one discontinuity. The size and configuration of the discontinuity can be sufficient to prevent circulating currents.

A further exemplary embodiment of the present disclosure is directed to a method of processing a substrate in a plasma processing apparatus. The plasma processing apparatus includes a RF energy applicator comprising at least one induction coil. The induction coil can be coupled to at least one resonant capacitor to form a resonant coil circuit. The method includes placing a substrate on the substrate holder within the interior of a processing chamber of a processing apparatus; admitting a process gas into the interior of the processing chamber; providing RF energy from an RF energy source through a match circuit and the resonant capacitor to the at least one induction coil to generate a substantially inductive plasma in the interior of the processing chamber; determining real power delivered to the substantially inductive plasma; and adjusting the RF energy in the at least one induction coil based on real power delivered to the substantially inductive plasma. In a variation of this exemplary embodiment, real power delivered to the plasma is determined based at least in part on power measurements performed using a power measurement device at a location between the match circuit and the at least one resonant capacitor.

Yet a further exemplary embodiment of the present disclosure is directed to an apparatus for processing a substrate in a plasma. The apparatus includes a processing chamber having an interior space operable to confine a process gas and a substrate holder in the interior of the processing chamber operable to hold a substrate. The apparatus further includes an RF energy source, a match circuit coupled to the RF energy source, and at least one resonant capacitor coupled to the match circuit. The apparatus further includes an inductive applicator disposed external to the processing chamber that includes at least one inductive coupling element. The inductive coupling element includes at least one coil coupled to the RF energy source through the at least one resonant capacitor and the match circuit. The apparatus further includes a power measurement device operable to measure real power at a location between the match circuit and the at least one resonant capacitor.

In a variation of this exemplary embodiment, the apparatus further includes a control loop configured to adjust energy applied to the inductive coupling element based at least in part on real power measured by the power measurement device.

Still a further exemplary embodiment of the present disclosure is directed to a method of processing a substrate in a plasma processing apparatus that includes a plurality of inductive coupling elements and a plurality of feed gas conduits. The method includes selectively distributing power to the plurality of inductive coupling elements to obtain a plasma profile; and controlling the flow rate of process gas in at least one of the plurality of feed gas conduits to spatially tune the distribution of charged and neutral species within the plasma.

Still a further exemplary embodiment of the present disclosure is directed to an electrostatic shield for use with a plasma processing apparatus. The electrostatic shield is configured to be disposed between an inductive coupling element that includes at least one coil and an interior of a process chamber.

In a variation of this exemplary embodiment, the electrostatic shield includes an array of thin metal strips disposed in a direction normal to the at least one coil of the inductive coupling element. The electrostatic shield can include at least one conductive loop. In a particular embodiment the conductive loop can be broken. In variations of this particular embodiment, the conductive loop can be grounded, floating, or maintained at a specified voltage.

In another variation of this exemplary embodiment, the electrostatic shield can include a flat sheet running parallel to the coil portion of the inductive coupling element. The flat sheet can include at least one discontinuity. The size and configuration of the discontinuity can be sufficient to prevent circulating currents.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1A provides a simplified cross-sectional view of a portion of a cylindrical inductive plasma processing chamber according to an exemplary embodiment of the present disclosure;

FIG. 1B—provides a simplified cross-sectional view of a portion of a cylindrical inductive plasma processing chamber according to another exemplary embodiment of the present disclosure;

FIG. 1C—provides a simplified cross-sectional view of a portion of a cylindrical inductive plasma processing chamber according to another exemplary embodiment of the present disclosure;

FIG. 2—provides a simplified downward cross-sectional view of the applicator wall shown in FIG. 1A;

FIG. 3A—provides a simplified perspective view of an exemplary inductive coupling element comprising a generally U-shaped magnetic flux concentrator disposed adjacent a thin dielectric window on an applicator wall of a chamber according to an exemplary embodiment of the present disclosure;

FIG. 3B—provides a simplified cross-sectional view of the exemplary inductive coupling element of FIG. 3A;

FIG. 3C—provides a simplified perspective view of an exemplary inductive coupling element comprising a generally U-shaped magnetic flux concentrator disposed adjacent to a thick dielectric window on an applicator wall of a chamber;

FIG. 4—provides a simplified cross-sectional view of an exemplary inductive coupling element comprising a generally E-shaped magnetic flux concentrator in a position on an applicator wall of a chamber according to an exemplary embodiment of the present disclosure;

FIG. 5—provides a simplified inside view of the top applicator wall of a cylindrical processing chamber according to an exemplary embodiment of the present disclosure;

FIG. 6—provides an exemplary circuit diagram for delivering power to an inductive coupling element according to an exemplary embodiment of the present disclosure;

FIG. 7—provides an upward view of an exemplary inductive coupling element adjacent to a dielectric window having an electrostatic shield according to an exemplary embodiment of the present disclosure;

FIG. 8—provides an upward view of an exemplary inductive coupling element adjacent to a dielectric window having an electrostatic shield according to another exemplary embodiment of the present disclosure;

FIG. 9—provides an upward view of an exemplary inductive coupling element adjacent to a dielectric window having an electrostatic shield according to yet another exemplary embodiment of the present disclosure;

FIG. 10—provides an upward view of an exemplary inductive coupling element adjacent to a dielectric window having an electrostatic shield according to yet another exemplary embodiment of the present disclosure;

FIG. 11—provides a simplified view of a scalable plasma processing apparatus having a rectangular shape;

FIG. 12—provides a close up view of an exemplary inductive coupling element used in the scalable plasma processing apparatus of FIG. 11—; and

FIG. 13—provides a cross-sectional view of a plurality of exemplary inductive coupling elements used in the scalable plasma processing apparatus of FIG. 11.

### DETAILED DESCRIPTION OF THE DRAWINGS

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Methods and apparatus to provide efficient and scalable RF inductive plasma processing are disclosed. In some aspects, the coupling between an inductive RF energy applicator and plasma and/or the spatial definition of power transfer from the applicator are greatly enhanced. The disclosed methods and apparatus thereby achieve high electrical efficiency, reduce parasitic capacitive coupling, and/or enhance processing uniformity.

Various embodiments comprise a plasma processing apparatus having a processing chamber bounded by walls, a substrate holder disposed in the processing chamber, and an inductive RF energy applicator external to a wall of the chamber. The inductive RF energy applicator comprises one or more radiofrequency inductive coupling elements (ICEs). Each inductive coupling element has a magnetic concentrator in close proximity to a thin dielectric window on the applicator wall.

The inductive coupling element is operable to send magnetic flux lines from the concentrator directionally through the thin dielectric window such that a substantial portion of the magnetic flux lines emerge from the dielectric window and continue downward into a volume of the chamber beneath the applicator. The flux lines curl laterally within this volume, then turn in an upward direction and return back to the dielectric window. A majority of the magnetic flux lines return from the interior of the chamber and through the dielectric window to the inductive coupling element. The high frequency magnetic flux lines from the concentrator, thus, surround a portion of plasma in the region immediately beneath the inductive coupling element. The magnetic flux can induce an electromotive force that is operable to power an inductively coupled plasma current in the region surrounded by the flux.

In particular embodiments, a conductive shield surrounds at least a portion of the magnetic flux concentrator of the inductive coupling elements. The conductive shield serves to further focus magnetic flux lines into the processing chamber interior and serves to isolate inductive coupling elements from other components of the plasma processing apparatus, such as other inductive coupling elements and feed gas conduits. The conductive shield also reduces power losses in the inductive coupling element arising from other components of the plasma processing apparatus, facilitating measurement of real power delivered to the plasma and enhancing process control.

The present subject matter can be embodied in various different forms. In the following description, for the purposes of explanation, numerous specific details are set forth to provide a thorough understanding of the disclosure. It will be apparent, however, to one skilled in the art, that the disclosed method and apparatus can be practiced without these specific details. In other instances, structures and devices are shown in simplified form in order to avoid obscuring the concepts. However, it will be apparent to one skilled in the art that the principles can be practiced in various different forms without these specific details. Hence aspects of the disclosure should not be construed as being limited to the embodiments set forth herein.

Reference in the specification to “one embodiment” or “an embodiment” means that a particular feature, structure, or characteristic described in connection with the embodiment is included in at least one embodiment. The appearances of the phrase “one embodiment,” “an embodiment” etc. in various places in the specification are not necessarily all referring to the same embodiment, nor are separate or alternative embodiments mutually exclusive of other embodiments.

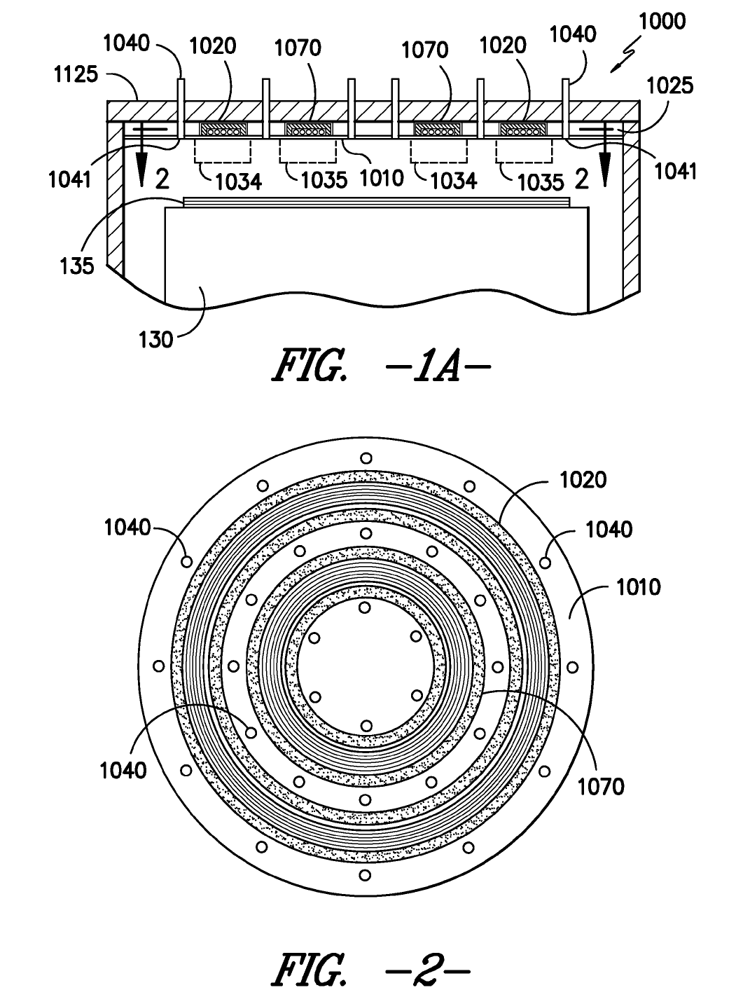

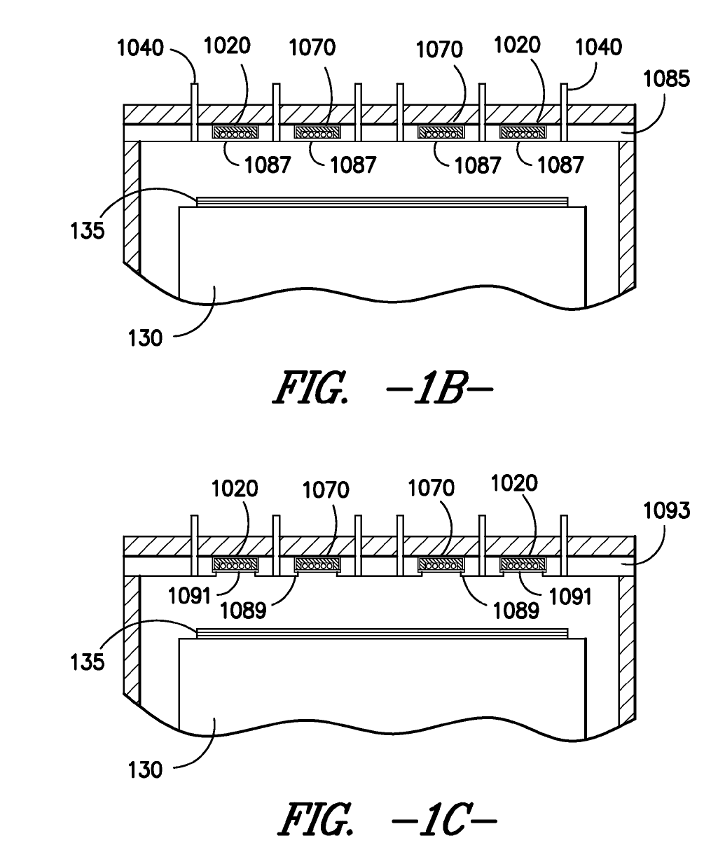

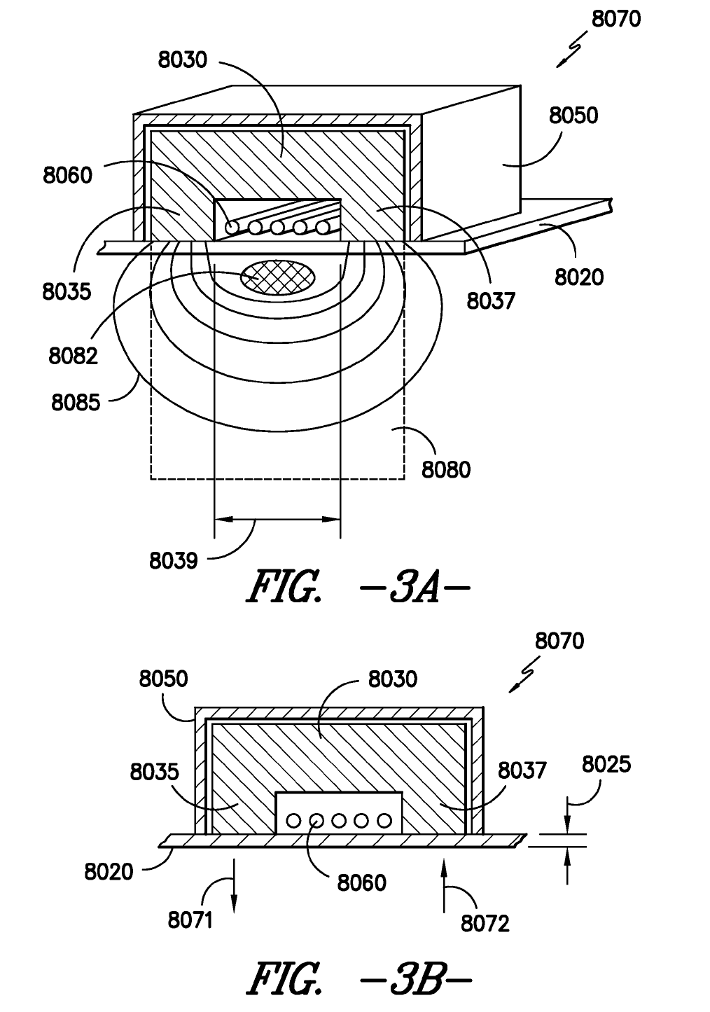

An embodiment of an applicator and processing chamber can be further understood with respect to a cylindrical chamber shown with respect to FIG. 1A—. FIG. 2—shows a downward cross-sectional view along line 2-2′ of the cylindrical chamber 1000 shown in FIG. 1A—. Processing chamber 1000 includes a substrate 135 disposed on a substrate holder 130, such as an electrostatic chuck or other substrate holder, in the interior of process chamber 1000. The applicator can comprise a plurality of inductive coupling elements such as ICEs 1020, 1070 at various positions over a thin window 1010 in the applicator wall of a chamber 1000. The ICE's 1020, 1070 are operable to circulate RF magnetic flux through respective annular volumes 1034 and 1035 localized beneath the respective ICE on the applicator wall of the chamber 1000. The flux from each ICE 1020, 1070 can induce an electromotive force in the respective annular volume 1034, 1035 of the chamber below. The induced electromotive force can in turn power a plasma current in a portion of the volume encircled by flux. By such currents, power can be efficiently transferred from each ICE 1020, 1070 to the respective localized volume 1034, 1035 below.

In a number of embodiments, feed gas can be introduced into the chamber through a plurality of feed gas holes 1041 in an applicator wall. The feed holes 1041 can receive process gas through tubulations such as feed gas conduits 1040. It has been found that introducing feed gas through holes interspersed among ICEs over the substrate provides excellent process uniformity and profile control. For instance, as illustrated in FIG. 1A—, feed gas conduit 1040 and feed hole 1041 are arranged such that process gas is delivered adjacent to localized volume 1034. This enhances the production of neutral and charged species in the inductive plasma generated in localized volume 1034.

Furthermore, in some applications, processing uniformity can be improved based on delivering a plurality of suitable feed gas flow rates through the various holes 1040. For example, each feed gas conduit 1040 and feed hole 1041 with respect to FIG. 1A—and/or FIG. 2—can be configured to admit a preselected flow rate of process gas to chamber 1000. These flow rates can be adjusted based on desired processing parameters. For instance, the control of various flow rates of feed gas from different feed gas conduits 1040 into the process chamber 1000 can provide for the efficient and separate tuning of the spatial distribution of charged and neutral species generated in the process gas during plasma processing.

In some processing applications, the interior volume of the processing chamber is maintained at low pressure. A preselected chamber pressure can be maintained using conventional pressure sensing devices (capacitance manometers, ion gauges, liquid manometers, spinning rotor gauges, and others), pumps such as oil based pumps, dry mechanical pumps, diffusion pumps, and others, and pressure control means such as automatic feedback control systems and/or conventional manual controls. Various embodiments do not depend on having any specific type of pumping system, pressure sensing means, or a preselected pressure. In vacuum processing applications, the applicator wall, and the lateral chamber walls, can support a pressure differential of at least one atmosphere.

Two annular ICEs 1020, 1070 over thin dielectric window areas in an applicator wall are depicted in FIGS. 1A—, 1B—, 1C—and FIG. 2. However an applicator wall can be configured with a greater number of ICEs at various preselected positions adjacent to an associated thin dielectric window area. The cross sectional area of the chamber can be scalably increased by adding a suitable number of ICEs at suitable positions on the applicator wall in proportion to the area. These ICEs can be positioned in a manner that will distribute power and maintain processing uniformity. In some embodiments, a relatively constant amount of real average power is deposited into each new increment of scaled area.

The term dielectric window area in an applicator wall will be understood to reference the portion of a thin window immediately adjacent to an ICE, through which a substantial portion of the magnetic flux lines from that ICE enter and/or return from the chamber interior in a relatively uniform direction. It will be understood that applicator walls and/or thin window areas can be configured in various different ways. For example, as shown with respect to FIG 1A—, a thin dielectric window disk 1010 such as quartz, a ceramic, etc., can span an entire upper surface of a chamber and be supported by mechanical bonding with overlayer 1125.

In various embodiments, such as shown with respect to FIG. 1B—, a unibody applicator wall 1085 can be comprised of a single dielectric disk having cavities above thin dielectric window areas 1087 operable for installing ICEs 1020, 1070. The relatively thick areas of the unibody can support atmospheric pressure across the span of the upper applicator wall 1085.

In various aspects, the thin dielectric windows 1087 are relatively narrow to have sufficient mechanical strength to support external atmospheric pressure when there is vacuum in the chamber. Thus, the width of thin window areas 1087 with respect to FIG. 1B—, on the other hand, is sufficiently narrow to sustain atmospheric pressure against a chamber vacuum with a sufficient margin of safety.

Other embodiments have at least one thin and relatively narrow discrete dielectric window segment disposed in a recess and/or channel of a relatively thick, load bearing chamber wall. The thin dielectric window in the recess (trough) is interposed between an ICE and the plasma processing chamber. The thin window and receiving channel width are sufficiently narrow to allow the relatively thin dielectric window to withstand atmospheric pressure. For instance, as illustrated in FIG. 1C—, lips 1089 in a thick wall 1093 provide support for thin dielectric windows 1091 in a trough. Dielectric windows 1091 are sufficiently narrow to support external atmospheric pressure from a vacuum in the chamber.

There arc embodiments where a low pressure differential across a large thin window, such as shown in FIG. 1A—, can be maintained by applying a fluid pressure and/or vacuum to channels in communication with a space above the window and/or in a supporting structure comprising troughs for the ICEs (not shown in the figures). A suitable pressure differential across the window can be maintained using various means such as a control loop operable to pressurize and/or evacuate in the channels based on sensing a chamber pressure.

In various embodiments a chamber profile is approximately a circular cylinder comprising at least one ICE above a dielectric window in a flat applicator wall at upper interior end of the chamber. However, chamber shape does not limit the scope of the claims. In further embodiments the cross-section of a chamber can be rectangular, elliptical, polygonal, and others.

In further embodiments, the various ICEs can be selectively powered in a manner operable to optimize plasma uniformity and/or obtain various other processing characteristics such as an electron density and/or energy distribution, a reactive species concentration profile, a degree of feed gas decomposition, and/or others. For example, in some embodiments a relatively greater amount of power can be deposited at the periphery of a processing chamber, to compensate for species loss and lower concentration from diffusive loss to the peripheral walls around the chamber and in other embodiments. In yet another example, the power sent to some and/or all of the ICEs is pulsed at a suitable rate and duty to produce precursor species for low stress films.

Preselected voltages, currents and/or power can be applied to the various ICEs using suitable matching networks. An exemplary power circuit and control loop for controlling voltages, currents, and/or power to ICEs will be discussed in more detail below with reference to FIG. 6—. Furthermore, the various ICEs can be driven with DC and/or RF potentials that have predetermined values relative to a chamber surface (a reference ground). The current and/or voltage applied to one ICE can have a preselected phase relative to either the current and/or voltage applied to a different ICE, and/or a chamber surface. The magnitudes and/or phases of the voltage applied to one or more ICE's can be selected to effectuate predetermined electron and/or ion energy and/or number distribution characteristics. Furthermore, the magnitudes and phases can be selected to effectuate a preselected plasma potential relative to various electrically conducting surfaces in the chamber. In a number of embodiments, a relatively low plasma potential is selected to avoid energetic particle bombardment of chamber surfaces. For example, the voltage applied to each ICE can be balanced relative to a common reference potential such as a chamber ground. Balancing can be useful to avoid and/or mitigate capacitive coupling between the ICE and plasma and DC plasma potential offset with respect to the chamber. However, in some applications the voltage(s) applied individually to one or more ICEs, or between different ICEs are selectively unbalanced with respect to one another and/or to the chamber. A selected RF voltage imbalance can be useful to effectuate a predetermined time-average DC voltage offset between the plasma and a wafer, chuck, and/or other chamber surface for processing. Still further, power waveform attributes such as an amplitude modulation (including pulsing), frequency modulation, and/or phase modulation may be selectively applied individually to one or more ICE's, or differentially between different ICEs, depending on the application. For example, suitable pulsing of high frequency RF excitation can be useful to modify chemical and/or mechanical properties for plasma depositing silicon nitride films.

It has been found that an ICE comprising a magnetic flux concentrator can send magnetic flux relatively directionally and deeply into the interior chamber immediately below the ICE. More particularly, the directionality of magnetic flux emitted from the ICE through a thin window and immediately below the dielectric window into the chamber can be controlled using a magnetic flux concentrator and a sufficiently thin window.

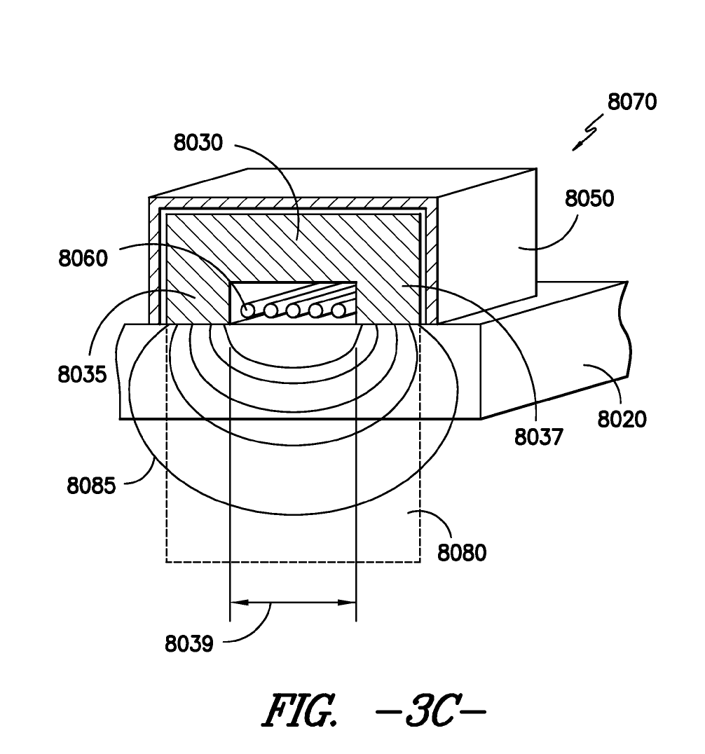

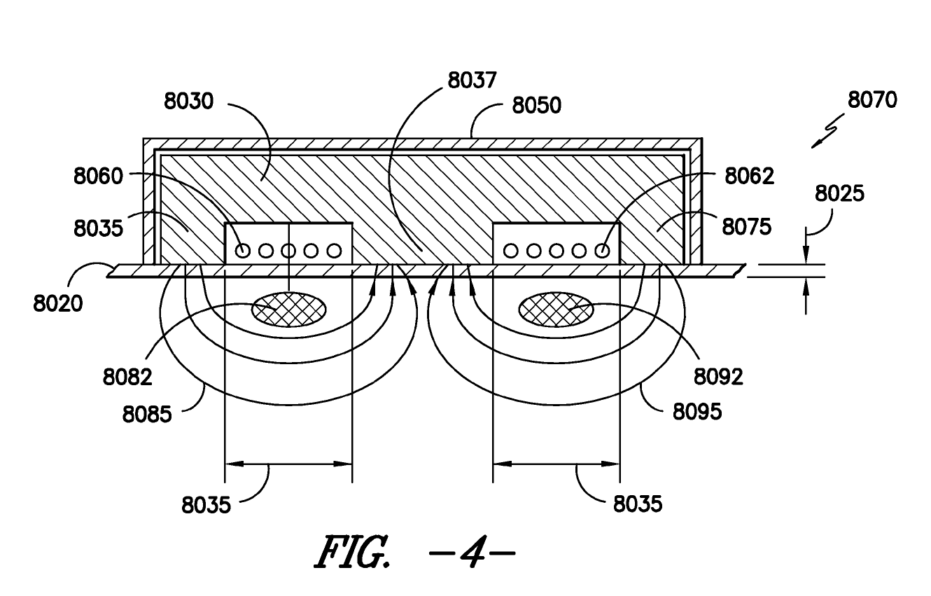

The synergistic operation of an ICE having a magnetic flux concentrator and an adjacent thin window on an applicator wall can be further understood with respect to the simplified diagram of FIG. 3A—and FIG. 3B—. As illustrated, ICE 8070 comprises magnetic flux concentrator 8030 and flat coil 8060. The ICE 8070 also includes a highly conductive shield 8050 over at least some portions of its bordering areas (e.g. upper and/or lateral peripheral areas of the ICE 8070).

The magnetic flux concentrator 8030 can comprise magnetically permeable material such as a ferromagnetic metal, a ferrite, and/or others. In various embodiments, a magnetic flux concentrator 8030 can include magnetically permeable material having a magnetic permeability of at least 10 relative to vacuum. In FIGS. 3A—and 3B—, a conductive shield 8050 is disposed over at least portions of the upper and/or lateral areas of an ICE 8070. In various embodiments, conductive shield can be effectuated by a structure encasing the ICE. For example, with respect to FIG. 1A—, proximate portions of members 1025 and/or 1125 defining a trough around ICE 1020 and/or 1070 can be comprised of a highly conductive metal such as aluminum, copper, silver and/or gold. In various embodiments, members 1025 and/or 1125 can be a conductive metal material.

Magnetically permeable material can reduce magnetic path resistance for magnetic flux lines in the concentrator medium. Accordingly, upper portions of magnetic flux lines 8085 are found to be generally confined within the concentrator, although a relatively small amount of leakage is possible. Highly conductive shielding, such as disclosed above, has been found to be effective as a barrier to electric and magnetic field lines emanating from structures in an ICE. In various embodiments, shielding over various portions of an ICE was found to improve magnetic flux confinement. Furthermore, a highly conductive shield is useful to reduce and/or eliminate parasitic power loss and/or electromagnetic interference in some embodiments.

ICE 8070 can be powered using high frequency voltage and/or current applied to the terminals of a coil 8060. In various embodiments, the coil can be flat. A flat coil 8060 comprising parallel conductors adjacent to thin dielectric window 8020 has been found to be particularly effective. High frequency current flowing in the coil 8060 can stimulate magnetic flux lines 8085 circulating through a localized volume 8080 adjacent to the dielectric window 8020 in a processing chamber.

In various embodiments, high frequency current through the coil 8060 is operable to power magnetic flux lines 8085 generally emanating from a first momentary pole area 8035 of the magnetic flux concentrator 8030, through an area of thin window 8020 and into the chamber. The magnetic flux lines 8085 circulate through a localized volume 8080 adjacent to the window area in the chamber, and return to the window area in a relatively uniform direction to a second momentary pole area 8037, different from 8035. The magnetic flux concentrator 8030 can be configured to emit magnetic flux lines 8085 generally in a predetermined first direction 8071 (FIG. 3B—) from the first pole area 8035 and return the circulating magnetic flux lines in a generally predetermined second direction 8072 (FIG. 3B—) to the second pole area 8037.

Where magnetic flux is emitted from an ICE in this manner, excellent power coupling and high power transfer efficiency can be effectuated. Furthermore, since the magnetic flux circulated from a magnetic flux concentrator can induce plasma current selectively in a volume of plasma immediately below the ICE, power can be transferred from the ICE directly into this volume. Accordingly, the plasma current and power can be deposited from an ICE into a preselected localized volume in the processing chamber.

In various embodiments, having flux emerge through a thin window chamber into the process chamber and return through the thin window from the chamber depends on having the momentary pole faces 8035, 8037 of a magnetic flux concentrator generally face the thin window and be within a minimum useful distance t_{w} of the interior chamber space below. With respect to FIG. 3A—, concentrator pole faces 8035 and 8037 generally face thin window 8020 and lie approximately one window thickness 8025 from the interior. It has been found that the value of a minimum useful distance t_{w}, depends on the gap distance between the momentary pole faces 8035 and 8037 of the concentrator (gap distance 8039).

For instance, FIG. 3A—illustrates an embodiment where the momentary pole faces 8035, 8037 of magnetic flux concentrator 8030 lie within a minimum useful distance of the chamber interior. As illustrated, a substantial portion of the magnetic flux 8085 emerges from the first pole area 8035 and passes through dielectric window 8020 into the process chamber interior and returns from the process chamber interior through dielectric window 8020 to the second pole area 8037. As used herein, a substantial portion of magnetic flux refers to at least about 10 percent of the total magnetic flux emanating from the ICE.

In contrast, FIG. 3C—illustrates a magnetic flux concentrator 8030 disposed adjacent to a thick dielectric window 8020 such that the pole faces 8035, 8037 of the magnetic flux concentrator 8030 do not lie within a minimum useful distance of the chamber interior. As illustrated, a portion of the magnetic flux lines 8085 do not pass through the dielectric window 8020 into the chamber interior. Rather, much of the magnetic flux 8085 remain inside dielectric window 8020 and never reach the chamber interior.

With respect to FIG. 3A—, the gap distance D_{g} between momentary pole faces 8035 and 8037 (measured from borders of the flux emitting and receiving areas) is marked with reference number 8039. It has been found that where t_{w} is less than a distance approximately D_{g}/4 from the chamber interior (e.g. the separation between the ICE and chamber interior 8020 is no greater than one-fourth of the distance between momentary pole faces) flux can emerge through a thin window into a chamber interior and return to the thin window from the chamber interior. More preferably, each contiguous area of an ICE that emits and/or receives a significant proportion of the total magnetic flux entering thin window area is less than a distance t_{w} of approximately D_{g}/8 from the interior volume of the chamber. However, a distance t_{w} of approximately D_{g}/2 still produces acceptable results.

In various embodiments with respect to FIG. 3A—and FIG. 3B—, a magnetic flux concentrator has a U-shape and/or C-shape. In such configurations, flux is generally emitted from an area ending one leg of the U and/or C-shape concentrator and received in an area ending in the other leg. The pole areas ends of the legs can be parallel to a thin window on the applicator wall as shown. In further configurations, a magnetic flux concentrator can comprise a plurality flux emitting and/or flux receiving areas facing a thin window.

The directionality of magnetic flux emitted from an ICE through a window and immediately below the window into the chamber depends on geometry and physical properties of the magnetic flux concentrator, the conductive shield disposed around the magnetic flux concentrator, and the dielectric window. It has been found that an ICE comprising a magnetic flux concentrator can send magnetic flux through the dielectric window and deeply into the chamber immediately below the ICE through the dielectric window. The material around the magnetic flux concentrator also plays an important role. Currents which may be induced in that material affect the magnetic fluxes, and losses, and depending on conductivity of the material, can improve performance or deplete performance. For example, if a highly conductive shield at least partially surrounds the magnetic flux concentrator, currents induced on the surface do not result in any significant losses, but can increase the magnetic flux inside the magnetic flux concentrator and thus, increase magnetic flux in the plasma adjacent to the dielectric window. On the other hand, if conductivity is low, losses induced in the shield can be large, while effect on magnetic flux might be low. Finally, material and geometry of the magnetic flux concentrator preferably includes a high magnetic flux density, low dissipation factor, and relatively wide foot at the base of U or C shaped magnetic flux concentrator. Otherwise, magnetic flux lines will exit and enter the magnetic flux concentrator at a wide angle distribution other than close to a preferred perpendicular direction.

A different embodiment can be understood with respect to FIG. 4—. FIG. 4—shows an ICE 8070 comprising flat parallel coil windings 8060, 8062 and an E-shape magnetic flux concentrator 8030. A first RF current is made to flow into flat coil windings 8060 and a second antiphase RF current is made to flow into flat coil windings 8062 (e.g. the currents into the respective windings are 180 degrees out of phase). One group of flux lines 8085 resulting from the current in windings 8060 can be emitted from a first pole area 8035 and/or be received in a portion of a second pole area 8037. Another group of flux lines 8095 resulting from the current in windings 8062 can be emitted from area 8075, and/or received in a portion of the second area 8037. Each respective group of magnetic flux lines can induce an electromotive force within the chamber operable to power plasma currents 8082, 8092 in respective volumes under the ICE 8070. These induced plasma currents 8082, 8092 are in a localized volume under the thin window area beneath the ICE, and between the several concentrator pole faces of the magnetic flux concentrator 8030.

Here the distance D_{g} between adjacent momentary pole faces is marked with reference number 8035. Also, the distance separating the pole faces from the chamber interior is approximately the thickness of the thin window 8025. In this configuration, the flux from pole faces 8035 and/or 8075 can emerge from the pole faces and through thin window 8020 into the process chamber interior. In a particular configuration, the thin window 8020 has a thickness 8025 of less than about D_{g}/4 and more preferably less than D_{g}/8.

In general, a relatively higher coupling coefficient between an external applicator and ICP in a chamber is attained as distance between the applicator and interior of the chamber is reduced. In various embodiments, a thin window allows the applicator to be relatively proximate to the process gas in which an ICP is sustained in the processing chamber. A relatively high coupling coefficient between the applicator and ICP generally results in more efficient power transfer.

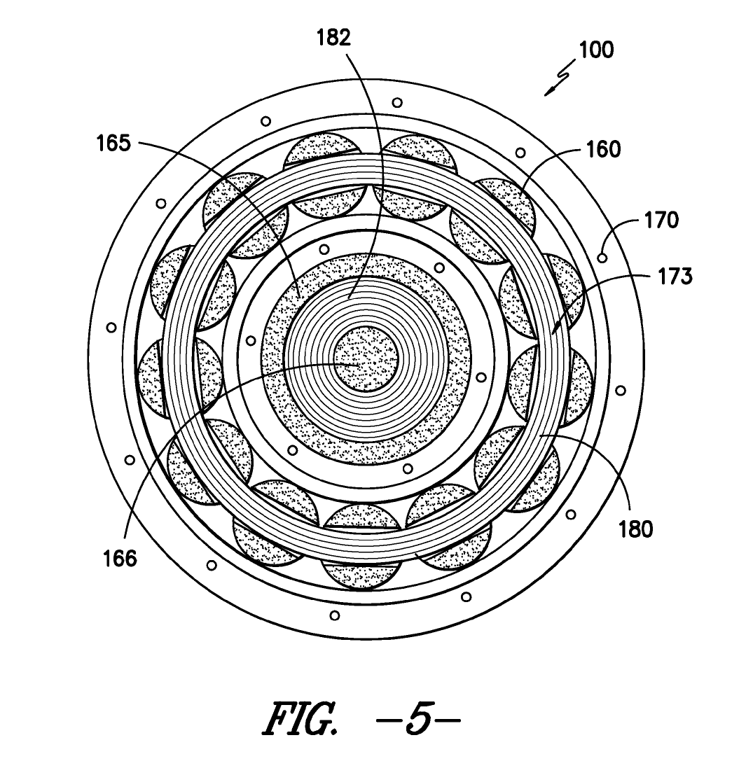

Additional embodiments can be understood with respect to FIG. 5—. FIG. 5—shows an inside upward facing view of an applicator 100 in a cylindrical processing chamber. Inductive applicator 100 comprises a plurality of ICEs having like ferrite core magnetic flux concentrators 160 in an outer ring. Each of the like magnetic flux concentrators has a round cross section and a U-shaped channel 173 in a side facing the chamber volume. Parallel coil turns 180 run through channels 173 in the cores. The channels 173 of the respective concentrators are aligned in a manner that can effectuate magnetic flux lines and a plasma current substantially similar to an axisymmetric circular ICE such as was shown with respect to FIGS. 1A—, 1B—, and 1C—. The inductive applicator 100 further comprises a central axisymmetric ICE comprising flat parallel coil conductors 182 in a trough between a central leg 166 and an outer leg 165 of a magnetic flux concentrator.

There is a thin disk shaped dielectric window (not apparent) above the ICE's and its supporting structure. The thin dielectric window is in contact with the various ICE's and the flat coil turns. Gas can be delivered into the interior 190 of the chamber through feed gas holes 170 in the thin window. The thin window thickness is less than about 1/10 of the distance between the flux emitting and receiving areas (pole gaps) 160, 166, 165 of the magnetic flux concentrators. Therefore each of the pole faces is within a distance of 1/10 of the gap distance between pole faces from the interior of the chamber. This embodiment is operable to send flux lines directionally from each ICE through an adjacent thin window area, to circulate flux lines through a respectively localized volume in the chamber interior, and to return those flux lines to the ICE generally perpendicular through the thin window area. The circulating flux lines induce an outer plasma current ring in localized chamber volumes under the flat coil turns in the aligned troughs of the outer magnetic flux concentrators, and an inner plasma current ring under the flat coil rings in the trough of the inner ICE magnetic flux concentrator.

In various embodiments, ICEs can be selectively energized. In some embodiments, different selected amounts of power having a selected phase relationship can be coupled to the various inductive coupling elements of the applicator. Furthermore, in some embodiments process uniformity over a substrate can be effectuated based on selectively delivering suitable amounts of RF power to the various ICEs. For example, some embodiments comprise processing diagnostic measurements coupled to a control loop in a manner operable to deliver selected amounts of power from the various ICEs into various localized regions of volume under the thin windows.

FIG. 6 discloses an exemplary power circuit and control loop for delivering power to an ICE. As illustrated, RF energy source 610 delivers power through a match network comprising a TLT (transmission line transformer) 620 or any other kind of transformer (shown regular transformer) to ICE 640. Resonant capacitors 630 are coupled between transformer 620 and ICE 640. When RF energy is applied to ICE 640, a substantially inductive coupled plasma 650 is generated in a process chamber. Resonant capacitors 630 are sized and arranged such that the reactance of the capacitors 630 cancels the reactance of the ICE 640 and inductively coupled plasma 650 during processing of a substrate. Use of the above drive circuit provides the capability to monitor and control power delivered to the ICE 640 based on real power delivered to the plasma 650.

Any method of measuring power delivered to a system suffers from inaccuracies. Existing processing equipment typically monitors power using a power measurement device located at the match network. This power measurement device captures power delivered to the plasma, losses in the ICE, losses in the antenna cage outside the chamber, and losses inside the chamber. All of these parameters will be different for different chambers, requiring process control parameters to be adjusted, for instance, each time an ICE is replaced and for each different chamber. Moreover, measurement performed at the matching network is particularly sensitive to the current and voltage waveforms applied to the ICE due to large phase angle differences (close to 90°) between voltage and current waveforms at the matching network for any good (high Q-factor) coil.

Use of the power circuit and control loop of FIG. 6 provides for efficient monitoring of real power delivered to the plasma without the above disadvantages. As illustrated, a power measurement device 660, comprising a current sensor 662 and a voltage sensor 664, measures voltage and current at a location between the transformer match network 620 and the resonant capacitors 630. At this location, when using a frequency close to the resonant frequency, the phase shift between current and voltage is close to 0° and small variations in the phase of the voltage and current waveforms do not substantially affect power measurements and will be accurate even for irregular waveforms.

Moreover, because resonant capacitor 630 resonates with the inductance of the ICE 640 and plasma 650, the current is determined only by the active resistance of the ICE and plasma. The power delivered to any component (plasma, coil, other lossy elements such as the shield surround the ICE), is then simply the product of I²R_{coil} Because of the magnetic flux concentrators and highly conductive shields surrounding the ICE, losses in the ICE walls are small, making it easier to separate losses in the plasma from losses in the coil. The use of highly conductive shields at least partially surrounding the ICE also reduces interference from adjacent inductive coupling elements and feed gas conduits, further increasing the accuracy of power measurements.

As shown in FIG. 6—, voltage measurements performed by voltage sensor 664 and current measurements performed by current sensor 662 are provided to a signal calculator 670. Signal calculator 670 may be based on conventional analog devices like operational amplifiers (e.g. AD811) and wideband multipliers (e.g. AD835). The amplifier (in some cases a simple divider can be used) generates a signal R_{coil}I(t) at any given instant in time, t, and then the multiplier multiplies V(t)−R_{coil}I(t) by the current I(t). To extract a quasi-DC component from the product I(t)*[V(t)−R_{coil}I(t)] that is proportional to the power delivered to the plasma in real-time. A simple integrating RC circuit can be used to filter out RF components and leave only a DC component. The power is thus instantenously measured at each part of the RF cycle, making the measurement insensitive to the shape of the waveform. In particular embodiments, R_{coil} can be determined using a network analyzer without plasma and tuning the power circuit to resonant frequency.

After determining real power delivered to the plasma, signal calculator 670 provides a real power signal 680 representative of real power delivered to the plasma. This real power signal 680 can be used by control loop for manual or automatic adjustments to the power delivered to the ICE. Adjusting the power provided to the ICE based on real power measurements delivered to the plasma provides for more accurate and efficient control of the plasma process.

This sensing arrangement is of particular usefulness when driving multiple inductive coupling elements from a single Power generator and matcher, unlike commonly used systems that measure power upstream of the matcher.

ICEs may generate a noticeable amount of capacitively coupled plasma due to parasitic capacitive coupling of inductive elements in the ICE. Such capacitive coupling may be undesirable, leading to process non-uniformities and to sputtering of the applicator window. An electrostatic or Faraday shield is often used to reduce capacitive coupling of ICE coils to plasma. Existing electrostatic shields can significantly reduce ICE coupling to the plasma and inflict significant losses in RF power, both reducing inductively coupled plasma transfer efficiency.

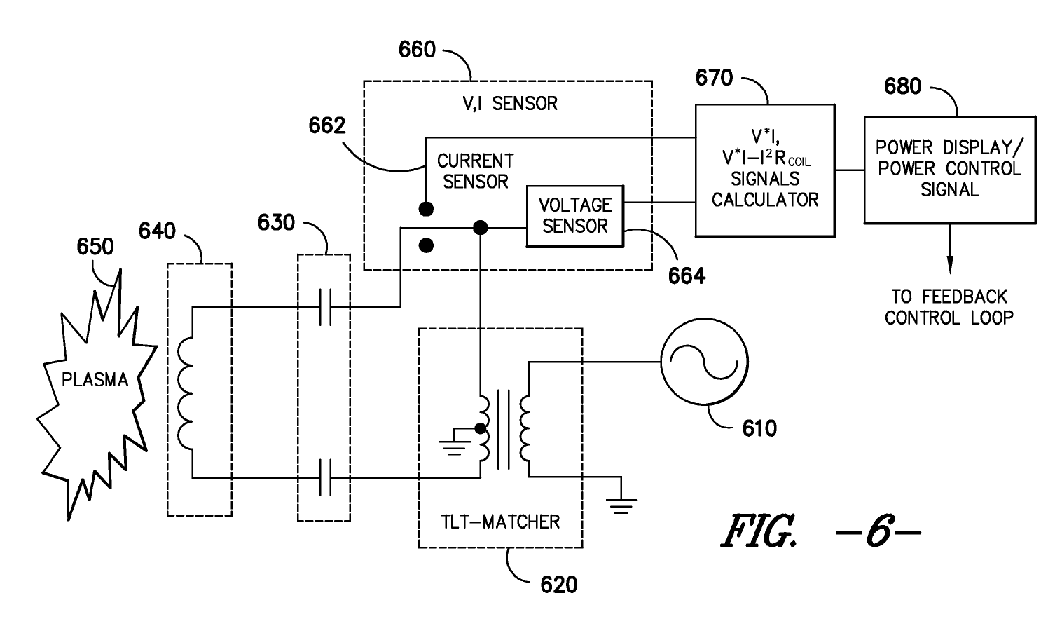

FIGS. 7—, 8—, 9—, and 10—provide various exemplary embodiments of improved electrostatic shields that can be used to reduce capacitive coupling in a plasma processing apparatus in accordance with the present disclosure. FIG. 7—provides an upward view of an exemplary ICE 740 disposed adjacent to a dielectric window 710. ICE 740 can include a coil and a magnetic flux concentrator. However, those of ordinary skill in the art, using the disclosures provided herein, should understand that the electrostatic shield embodiments disclosed herein can be used with any ICE without deviating from the scope of the present disclosure.

An electrostatic shield 720 is disposed on the dielectric window 710. Electrostatic shield 720 can be formed from any conductive material, such as copper, aluminum, silver, or other suitable conductor. Electrostatic shield 720 can be affixed to dielectric window 710 using any suitable process. For instance, electrostatic shield 720 can be screwed, glued, or deposited to the window. In a particular embodiment, electrostatic shield 720 can be adhered to dielectric window using thick film deposition or self-adhesive copper or aluminum foil.

Electrostatic shield 720 generally comprises an array of thin metal strips 722 disposed in a direction substantially normal to the coil of the inductive coupling element 740. The thin metal strips 722 are arranged close enough to each other to effectively shield electric fields from the process chamber interior. The electrostatic shield 720 nearly satisfies the condition of anisotropic conductivity. Namely, the conductivity of the electrostatic shield 720 is about zero in the direction of the inductively induced field and substantially large in the direction normal to the inductively induced field and tangent to the plasma surface.

As illustrated in FIG. 7, the array of thin metal strips 722 can be coupled together using a conductive loop 725 outside of the field applicator. While FIG. 7 illustrates two conductive loops 725, more or less conductive loops can be used without deviating from the scope of the present disclosure. For instance, in a particular embodiment, one conductive loop can couple the array of thin metal strips. The location of the conductive loop can also be modified. For instance, the conductive loop can run along either edge of the array of thin metal strips 722.

In a particular embodiment, conductive loop 725 can be coupled to ground or reference voltage. In an alternative embodiment, conductive loop 725 can remain floating to provide for a little amount of capacitive coupling through the electrostatic shield 720. A little capacitive coupling may be desired to help ignite or sustain the plasma or to intentionally introduce non-uniformities into the plasma. In another embodiment, conductive loop 725 can be coupled to a voltage source. The voltage applied to the conductive loop can be adjusted to control the amount of capacitive coupling through the electrostatic shield.

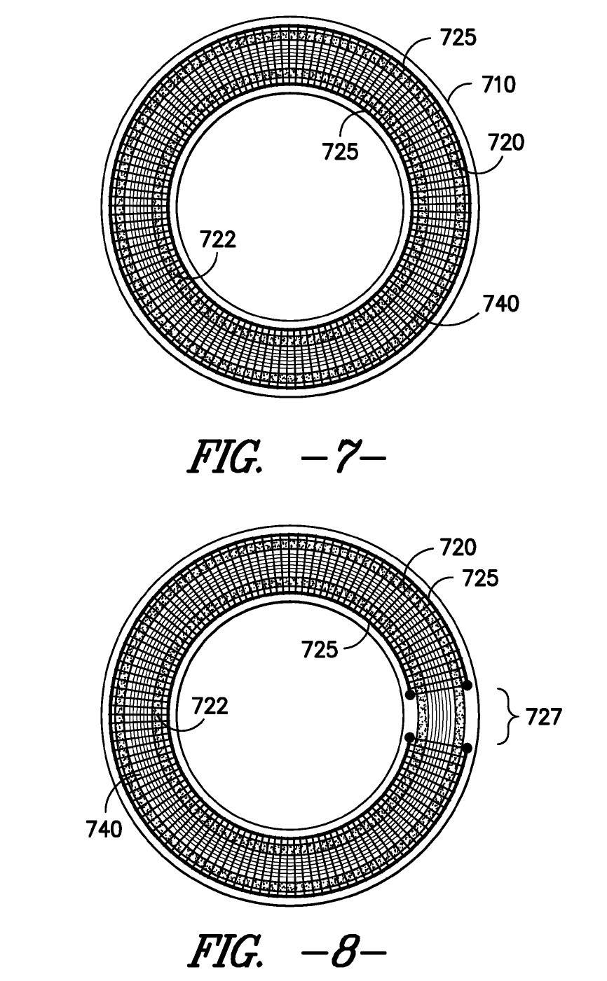

FIG. 8—illustrates an embodiment of an electrostatic shield 720 where conductive loops 725 are broken so as to form a gap 727. The electrostatic shield 720 of FIG. 8—has no closed conductive path and therefore no circulating RF currents. This provides for reduced RF power losses. The electrostatic shield 720 of FIG. 8—is suitable for screening of an unbalanced multi-turn antenna coil where one end of the coil is grounded. In this case, the electrostatic shield 720 can operate as an unclosed single turn with a grounded middle point. RF voltage equal to half of the inductively coupled electromotive force, but of opposite phase, are developed on the ends of electrostatic shield 720 across the gap 727. As a result, the capacitive coupling to the plasma is reduced.

FIG. 9—illustrates an embodiment of an electrostatic shield 720 that does not include a conductive loop. This particular screen can be sufficient only to reduce capacitive coupling so as to eliminate sputtering, but leave some capacitive coupling to create small azimuthal plasma non-uniformities and to help ignite and sustain a plasma. The electrostatic shield 720 of FIG. 9—may also be particularly effective in conjunction with a balanced ICE. Due to the balanced ICE, each metal strip in the array of 722 acts as a virtual ground to screen the ICE coil from plasma.

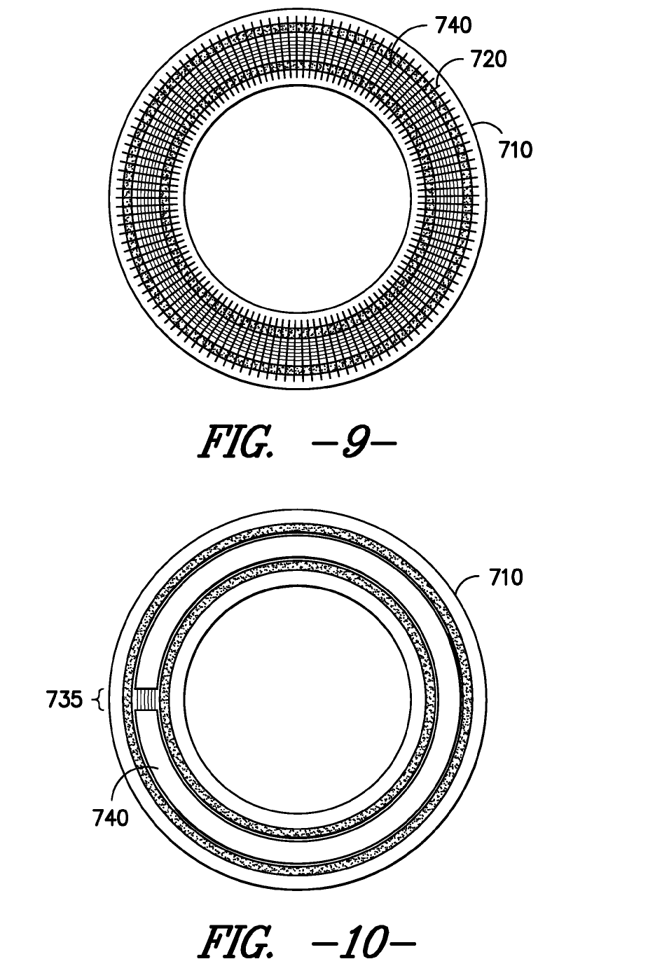

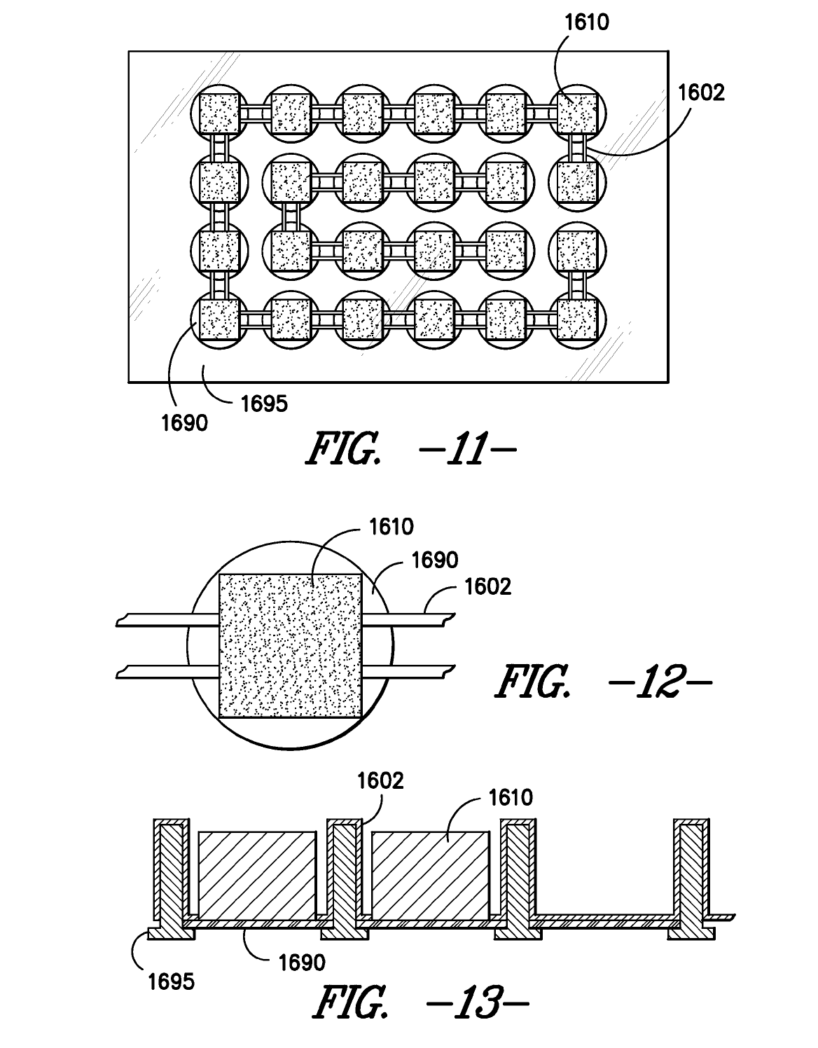

FIG. 10—illustrates yet another embodiment of an electrostatic shield 730 that can be used in accordance with embodiments of the present disclosure. Electrostatic shield 730 includes a flat sheet running parallel to the coil portion of the inductive coupling element. The electrostatic shield is preferably disposed on the dielectric window 720 such that the electrostatic shield is located between the pole faces of a magnetic flux concentrator of the inductive coupling element so that the pole faces are not covered. As illustrated, the flat sheet includes at least one discontinuity 735. Discontinuity 735 is preferably sized and deminensioned to prevent circulating currents in electrostatic shield 730. While one discontinuity 735 is illustrated in FIG. 10, more or less discontinuities can be included as desired. The electrostatic shield 730 of FIG. 10—does not fully shield capacitive coupling, but results in a great reduction of dielectric window sputtering. Moreover, any non-uniformities in capacitive coupling are not affected by electrostatic shield 730.

An embodiment for scalable processing of large rectangular substrates can be understood with respect to FIG. 11—, 12—, and 13—. The upper portion of FIG. 11—shows a top view of various ICEs arranged over thin dielectric disk-shaped windows in a rectangular array on a rectangular upper applicator wall 1695 over the interior volume of a rectangular chamber. Each ICE comprises flat coil conductors 1602 running in a trough through a U-shaped magnetic flux concentrator 1610. The various thin dielectric disk windows 1690 are supported on lips abutting the lower surface of a metal upper applicator wall structure 1695 over the interior chamber space. The thin dielectric disk windows 1690 are thinner than about 1/10 of the gap between legs of the U-shaped magnetic flux concentrators 1610. There can be interconnections between corresponding conductors 1602 of coil portions and pairs of adjacent ICEs.

In various embodiments, ICEs can be connected and/or powered in alternative manners. With respect to FIG. 11—, mere portions of an illustrative series-parallel ICE connection are shown. In further embodiments ICEs can be powered in different ways. For example, RF power can be selectively delivered to each of the various ICEs. In still further embodiments, a plurality of ICEs can be coupled in parallel, in series, or they can be combined into various combinations of series and parallel connections. The scope of the claims is not limited by ICE connection powering topology. Furthermore there can be a number of feed gas holes in the applicator wall and processes gases can be selectively introduced through such holes in various ways.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

1-33. (canceled)

34. An apparatus for processing a substrate, comprising:
a processing chamber having an interior space;
a substrate holder in the interior space;
at least one dielectric window constituting at least a portion of a wall of the processing chamber;
an inductive coupling element having a flat coil disposed proximate the dielectric window;
an electrostatic shield disposed between the inductive coupling element and interior space;
wherein the electrostatic shield comprises an array of metal strips, each of the metal strips disposed in a direction that is generally normal to the flat coil.

35. The apparatus of claim 34, wherein the array of metal strips are coupled by a conductive loop.

36. The apparatus of claim 35, wherein the conductive loop is broken.

37. The apparatus of claim 34, wherein the electrostatic shield is grounded.

38. The apparatus of claim 34, wherein the electrostatic shield is floating.

39. The apparatus of claim 34, wherein the inductive coupling element comprises a U-shaped magnetic flux concentrator disposed about the flat coil.

40. The apparatus of claim 34, wherein the magnetic flux concentrator has a first pole area and a second pole area facing the dielectric window.

41. The apparatus of claim 34, wherein a conductive shield is disposed at least partially around the magnetic flux concentrator.

42. An apparatus for processing a substrate, comprising:
a processing chamber having an interior space;
a substrate holder in the interior space;
at least one dielectric window constituting at least a portion of a wall of the processing chamber;
an inductive coupling element having a flat coil disposed proximate the dielectric window;
an electrostatic shield disposed between the inductive coupling element and interior space;
wherein the electrostatic shield comprises a flat sheet parallel to the flat coil, the flat sheet having at least one discontinuity

43. The apparatus of claim 42, wherein the electrostatic shield is grounded.

44. The apparatus of claim 42, wherein the electrostatic shield is floating.

45. The apparatus of claim 42, wherein the inductive coupling element comprises a U-shaped magnetic flux concentrator disposed about the flat coil.

46. The apparatus of claim 42, wherein the magnetic flux concentrator has a first pole area and a second pole area facing the dielectric window.

47. The apparatus of claim 42, wherein a conductive shield is disposed at least partially around the magnetic flux concentrator.
